(19) United States
(12) Patent Application Publication
(10) Pub. No.: US 2011/0108912 A1
(43) Pub. Date: May 12, 2011

(54) METHODS FOR FABRICATING TRENCH METAL OXIDE SEMICONDUCTOR FIELD EFFECT TRANSISTORS

(76) Inventors: Hamilton LU, Los Angeles, CA (US); Laszlo LIPCSEI, Campbell, CA (US)

(21) Appl. No.: 12/905,362

(22) Filed: Oct. 15, 2010

Related U.S. Application Data
(60) Provisional application No. 61/259,275, filed on Nov. 9, 2009.

(51) Int. Cl. H01L 29/772; H01L 21/336

(52) U.S. Cl. 257/331; 438/270; 257/E21.409; 257/E29.242

(57) ABSTRACT

A method for fabricating a cellular trench metal oxide semiconductor field effect transistor (MOSFET) includes depositing a first photoresist atop a first epitaxial (epi) layer to pattern a trench area, depositing a second photoresist atop a first gate conductor layer to pattern a mesa area, etching away part of the first gate conductor layer in the mesa area to form a second gate conductor layer with a hump, and titanizing crystally the second gate conductor layer to form a Ti-gate conductor layer. Edges of the mesa area are aligned to edges of the trench area. Hence, approximately more than half of polysilicon in the second gate conductor layer is titanized crystally. A spacer can be formed to protect corners of the first gate conductor layer and to make the gate conductor structure more robust for mechanical support.

### RELATED APPLICATION

This application claims priority to U.S. Provisional Application No. 61/259,275, titled “Methods for Fabricating Trench Metal Oxide Semiconductor Field Effect Transistor,” filed on Nov. 9, 2009, which is hereby incorporated by reference in its entirety.

### BACKGROUND

During the past few decades, there has been an increasing interest in semiconductor devices, such as a power metal oxide semiconductor field effect transistor (MOSFET) used in various applications. The power MOSFET usually has a polysilicon layer. The polysilicon layer can be used, for example, as a gate electrode of the power MOSFET.

The power MOSFET can have one of two major structures, e.g., a vertical diffused MOSFET (VDMOSFET) or a trench MOSFET. The VDMOSFET began available in the mid-1970s due to the availability of planar technology. By the late 1980s, the trench MOSFET started penetrating power MOSFET markets utilizing dynamic random access memory (DRAM) trench technology, which has improved the specific on-resistance between a drain terminal and a source terminal (RDSON) of the power MOSFET. However, gate charges in the trench MOSFET may limit high speed (or dv/dt) applications compared to DVMOSFET. The main tradeoff is between the RDSON and gate charges which are associated with poly gate resistance and capacitance.

### SUMMARY

Embodiments of the invention pertain to methods for fabricating a cellular trench metal oxide semiconductor field effect transistor (MOSFET). In one embodiment, the method includes depositing a first photoresist atop a first epitaxial (epi) layer to pattern a trench area, depositing a second photoresist atop a first gate conductor layer to pattern a mesa area, etching away part of the first gate conductor layer in the mesa area to form a second gate conductor layer with a hump, and titanizing crystally the second gate conductor layer to form a Ti-gate conductor layer. Edges of the mesa area are aligned to edges of the trench area. Hence, approximately more than half of polysilicon in the second gate conductor layer is titanized crystally. The poly sheet resistance of the cellular trench MOSFET can be reduced, and thus the gate conductivity of the cellular trench MOSFET is enhanced. A spacer can be formed to protect corners of the first gate conductor layer and to make the gate conductor structure more robust for mechanical support.

### BRIEF DESCRIPTION OF THE DRAWINGS

Features and advantages of embodiments of the claimed subject matter will become apparent as the following detailed description proceeds, and upon reference to the drawings, wherein like numerals depict like parts, and in which:

FIGS. 1-8 illustrate cross-sectional views of a fabrication sequence of a cellular trench metal oxide semiconductor field effect transistor (MOSFET), in accordance with one embodiment of the present invention.

FIG. 9 illustrates a cross-sectional view of a structure diagram of a trench MOSFET, in accordance with one embodiment of the present invention.

FIG. 10 illustrates a block diagram of a power conversion system, in accordance with one embodiment of the present invention.

FIG. 11 illustrates a flowchart of a method of fabricating a cellular trench MOSFET, in accordance with one embodiment of the present invention.

### DETAILED DESCRIPTION

In the following detailed description of the present invention, numerous specific details are set forth in order to provide a thorough understanding of the present invention. However, it will be recognized by one skilled in the art that the present invention may be practiced without these specific details or with equivalents thereof. In other instances, well-known methods, procedures, components, and circuits have not been described in detail as not to unnecessarily obscure aspects of the present invention.

Some portions of the detailed descriptions that follow are presented in terms of procedures, logic blocks, processes, and other symbolic representations of operations for fabricating semiconductor devices. These descriptions and representations are the means used by those skilled in the art of semiconductor device fabrication to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing terms such as “coating,” “depositing,” “etching,” “fabricating,” “siliciding,” “implanting,” “metalizing,” “titanizing” or the like, refer to actions and processes of semiconductor device fabrication.

It is understood that the figures are not drawn to scale, and only portions of the structures depicted, as well as the various layers that form those structures, are shown.

Furthermore, other fabrication processes and steps may be performed along with the processes and steps discussed herein; that is, there may be a number of processes and steps before, in between and/or after the steps shown and described herein. Importantly, embodiments of the present invention can be implemented in conjunction with these other processes and steps without significantly perturbing them. Generally speaking, the various embodiments of the present invention can replace portions of a conventional process without significantly affecting peripheral processes and steps.

In one embodiment, the present invention provides a method for fabricating a cellular trench metal oxide semiconductor field effect transistor (MOSFET). A first photoresist is deposited atop a first epitaxial (epi) layer to pattern a trench area. A second photoresist is deposited atop a first gate conductor layer to pattern a mesa area. Edges of the mesa area are aligned to edges of the trench area. Part of the first gate conductor layer in the mesa area is etched away to form a second gate conductor layer with a hump on top. Titanium (Ti) is deposited and then the Ti in the mesa area is etched away. Therefore, the hump is titanized crystally from the top and sidewalls of the hump simultaneously and the second gate conductor layer is titanized crystally in a downward direction from the top of the second gate conductor layer. Advantageously, more than half of a gate conductor material in the second gate conductor layer (which includes the hump) is converted to a Ti-gate conductor material; in a conventional recess etching technology, about 10% of the gate conductor material is converted. As a result of the present invention, the sheet resistance of a cellular trench MOSFET can be reduced, and thus the gate conductivity of a cellular trench MOSFET is enhanced. A spacer is formed to protect corners of the Ti-gate conductor layer and to make the gate conductor structure more robust for mechanical support.

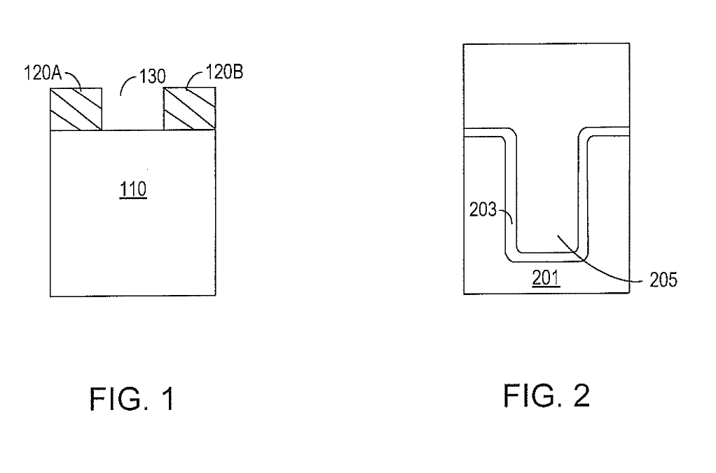

FIGS. 1-8 illustrate cross-sectional views of a fabrication sequence of a cellular trench metal oxide semiconductor field effect transistor (MOSFET), in accordance with one embodiment of the present invention. The fabrication sequence of the cellular trench MOSFET in FIGS. 1-8 is for illustrative purposes and is not intended to be limiting.

In FIG. 1, epitaxial deposition is performed to form an epi layer. For example, N-type epitaxial (Nepi) deposition is performed to form a Nepi layer 110 on the top of a semiconductor substrate of a wafer, e.g., an N-type heavily doped (N+) substrate (not shown in FIG. 1). Afterwards, a first photoresist is deposited to form photoresist regions 120A and 120B atop the Nepi layer 110. The photoresist regions 120A and 120B are coated on the Nepi layer 110 and act as masks to pattern a trench area for the cellular trench MOSFET, e.g., the location for the trench of the cellular trench MOSFET.

In FIG. 2, part of the Nepi layer 110 in the trench area is etched away by lithography means to form a trench. In other words, the silicon in the trench area is removed through an opening 130 shown in FIG. 1, thereby forming an active trench. As a result, a Nepi layer 201 is formed. The first photoresist is stripped away from the wafer's surface and the trench is then oxidized. Thus, a gate oxide layer 203 is grown around the Nepi layer 201. The gate oxide layer 203 surrounds the trench; that is, the gate oxide layer 203 coats the surfaces (sidewalls and bottom) of the trench. A gate conductor material is deposited and doped by phosphoryl chloride (POCl₃) to form a gate conductor layer 205 atop the oxide layer 203. More specifically, part of the gate conductor layer 205 fills the trench and the gate conductor layer 205 covers the oxide layer 203 with a predetermined thickness. The gate conductor material can be polysilicon, tungsten, germanium, gallium nitride (GaN), or silicon carbide (SiC).

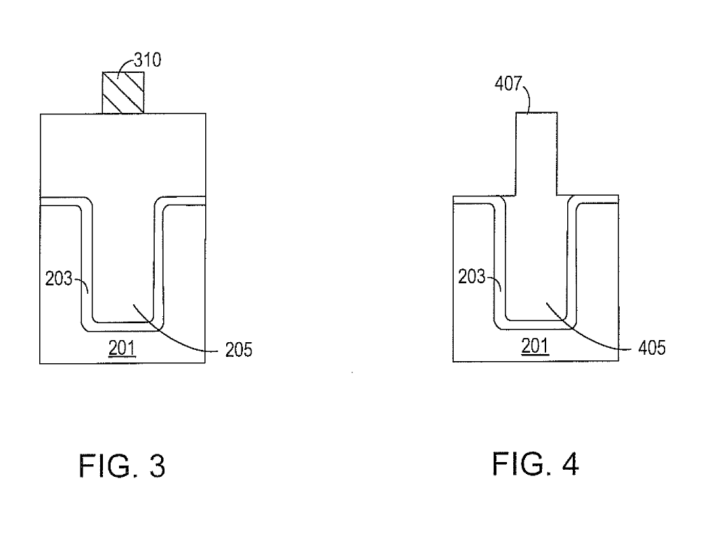

In FIG. 3, a second photoresist is deposited atop the gate conductor layer 205 to pattern a mesa area for the cellular trench MOSFET. The edges of the second photoresist are aligned to the edges of the first photoresist. As a result, a photoresist region 310 is formed atop the gate conductor layer 205. The edges of the photoresist region 310 are aligned to the edges of the photoresist regions 120A and 120B.

In FIG. 4, part of the gate conductor layer 205 in the mesa area shown in FIG. 3 is etched away to form a gate conductor layer 405 with a hump 407 on top. In one embodiment, the hump 407 is a rectangular hump. The hump 407 has a predetermined thickness, and the rest of the gate conductor layer 405 fills the trench of the cellular trench MOSFET. After the formation of the gate conductor layer 405, the second photoresist is stripped.

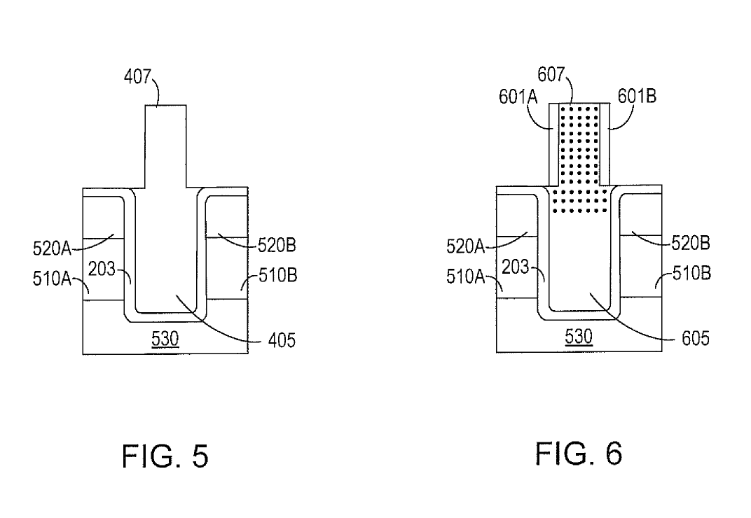

Afterwards, in FIG. 5, P-type dopants for the channel body are implanted and driven in the Nepi layer 201 to a certain depth to form P-wells 510A and 510B. In other words, the P-wells 510A and 510B are formed in the upper portion of the Nepi layer 201 using an implantation of P-type dopants into the Nepi layer 201 after formation of the gate conductor layer 405. The P-wells 510A and 510B atop a Nepi layer 530 can act as body regions of the trench. Subsequently, N-type dopants for the channel body are implanted and driven in to form N-type layers, e.g., N+ layers 520A and 520B, respectively, in the body regions of the trench. The N+ layers 520A and 520B are on the top of the P-wells 510A and 510B, respectively.

In FIG. 6, the gate conductor layer 405 is titanized crystally to form a Ti-gate conductor layer 605 after formation of the N+ layers 520A and 520B. The hump 407 (FIG. 5) is titanized crystally from the top and the sidewalls of the hump 407 simultaneously to form a titanized hump 607. The gate conductor layer 405 is titanized crystally in a downward direction from the top of the gate conductor layer 405 (FIG. 5). For example, a titanium (Ti) film is sputtered and annealed by rapid thermal anneal (RTA) or furnace to form Ti silicide in the Ti-gate conductor layer 605. More specifically, the Ti film is sputtered crystally from the top and the sidewalls of the hump 407 simultaneously. Then, the Ti film is continuously sputtered into the gate conductor layer 405 in a downward direction from the top of the second gate conductor layer 405. Afterwards, the anneal step is performed. The Ti in the mesa area can be etched away by peroxide wet etching, and the Ti-gate conductor material remains in the upper portion of the Ti-gate conductor layer 605 including the hump 607 as shown by the dotted region in FIG. 6 and the figures that follow.

Advantageously, compared to the conventional recess etching technology, more gate conductor material is included in the gate conductor layer 405 due to deposition of the second photoresist on the gate conductor layer 205 in FIG. 3. Compared to the conventional downward titanization, more gate conductor material in the gate conductor layer 405 can be converted to the Ti-gate conductor material. For example, approximately more than half (by volume) of the gate conductor material in the gate conductor layer 405 (including the hump 407) can be converted to the Ti-gate conductor material. Advantageously, more Ti-gate conductor material is formed in the Ti-gate conductor layer 605 compared to the conventional recess etching technology. The Ti-gate conductor layer 605 can form a gate region of the cellular trench MOSFET. Consequently, sheet resistance of the gate conductor material of the cellular trench MOSFET can be reduced because more gate conductor material of a poly gate is titanized crystally. In one embodiment, the sheet resistance of a gate region of the cellular trench MOSFET can be around 0.13 Ohm per square (Ohm/SQ). In other words, the sheet resistance of the cellular trench MOSFET can be approximately 0.13 Ohm/SQ. Advantageously, the gate conductivity of the cellular trench MOSFET can be improved due to more Ti-gate conductor material in the gate conductor structure.

Moreover, a spacer, e.g., low temperature oxide (LTO) spacers 601A and 601B are formed on the sidewall of the Ti-gate conductor layer 605 to protect corners of the Ti-gate conductor layers 605 from being damaged during successive implantation steps. Additionally, the spacers 601A and 601B can make the gate conductor structure more robust for mechanical support.

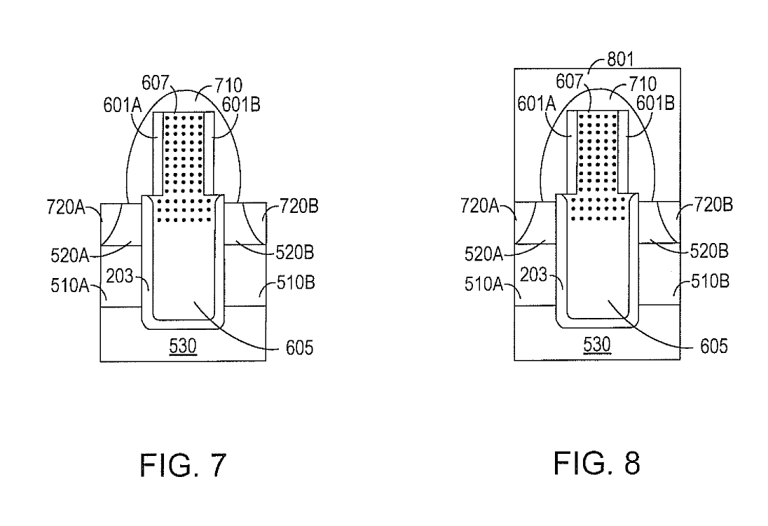

In FIG. 7, tetraethylorthosilicate (TEOS) and borophosphosilicate glass (BPSG) are deposited to form a TEOS and BPSG layer 710 atop the Ti-gate conductor layer 605 and around the spacers 601A and 601B. Afterwards, an implantation of P-type dopants followed by a drive-in step is performed to form P-type heavily doped (P+) layers 720A and 720B adjacent to the N+ layers 520A and 520B, respectively. Subsequently, the P+ layers 720A and 720B can be annealed and reflowed. The N+ layers 520A and 520B can form a source region of the cellular trench MOSFET. The P+ layers 720A and 720B can form a body diode contact. Hence, the contact etching is performed.

In FIG. 8, metallization is performed to separate gate and source metal connections. The entire cell can be metalized by a metal layer 801.

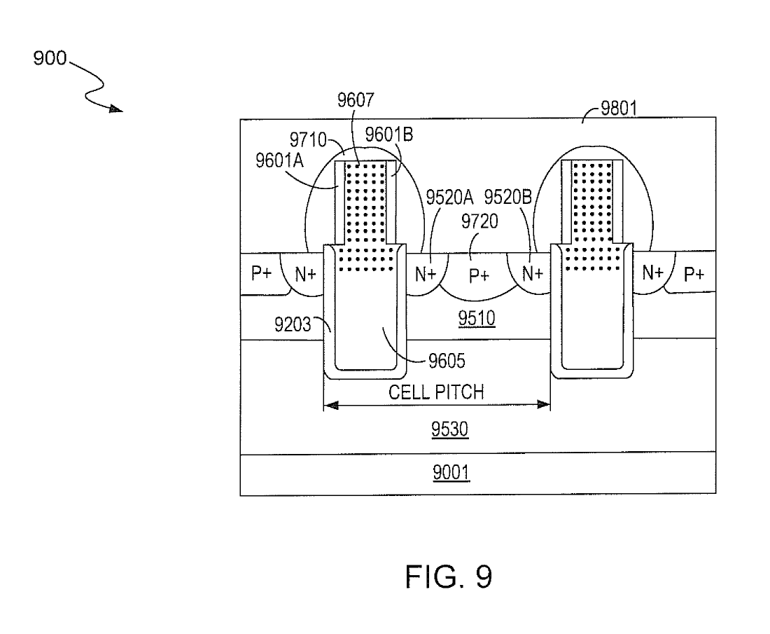

FIG. 9 illustrates a cross-sectional view of a structure diagram of a trench MOSFET 900, in accordance with one embodiment of the present invention. The trench MOSFET 900 is fabricated by the manufacturing processes and steps described in relation to FIGS. 1-8. In one embodiment, the trench MOSFET 900 can include multiple cells, e.g., the cellular trench MOSFETs fabricated by the manufacturing processes and steps shown in FIGS. 1-8.

In one embodiment, each cell can include an N+ substrate 9001. A Nepi layer 9530 is formed atop the N+ substrate 9001. A trench of the cell is filled with a Ti-gate conductor layer 9605 with a hump 9607 surrounded by a gate oxide layer 9203. The Ti-gate conductor layer 9605 includes a titanized region and a non-titanized region as described above; in one embodiment, about one-half of the layer 9605 (including the hump 9607) is titanized while the remainder of layer 9605 is not. Advantageously, due to deposition of the second photoresist in FIG. 3, more Ti-gate conductor material is included in the Ti-gate conductor layer 9605. In one embodiment, the sheet resistance of the Ti-gate conductor layer 9605 of the trench MOSFET 900 can be decreased. In other words, the sheet resistance of the trench MOSFET 900 can be reduced, e.g., from around 0.50 Ohm/SQ to around 0.130 Ohm/SQ. As a result, the gate conductivity of the trench MOSFET can be enhanced.

The surface of the Ti-gate conductor layer 9605 is smoothed by a spacer, e.g., LTO spacers 9601A and 9601B. The Ti-gate conductor layer 9605 can constitute a gate region of the trench MOSFET 900.

A trench body, e.g., a P-well 9510, is formed atop the Nepi layer 9530. A P+ layer 9720 and N+ layers 9520A and 9520B are formed within the P-well 9510. In one embodiment, the P+ layer 9720 acting as a body diode contact is located between the N+ layers 9520A and 9520B. The N+ layers 9520A and 9520B can constitute a source region of the trench MOSFET 900. The bottom layer, e.g., the N+ substrate 9001, can constitute a drain region of the trench MOSFET 900.

In one embodiment, a metal layer 9801 can be formed atop a TEOS and BPSG layer 9710 and the source region. The TEOS and BPSG layer 9710 can separate gate and source metal connections.

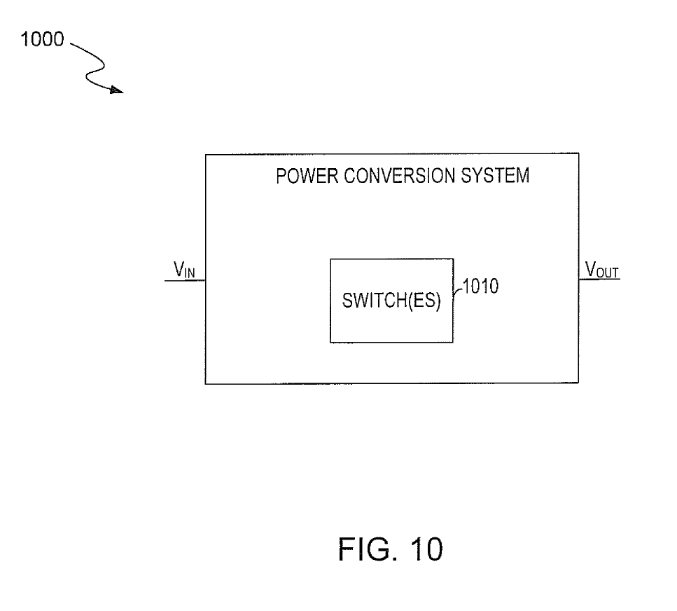

FIG. 10 illustrates a diagram of a power conversion system 1000, in accordance with one embodiment of the present invention. In one embodiment, the power conversion system 1000 can converter an input voltage to an output voltage. The power conversion system 1000 can be a direct current to direct current (DC-DC) converter, an alternating current to direct current (AC-DC) converter, or a DC-AC converter. The power conversion system 1000 can include one or more switches 1010.

In one embodiment, the switch 1010 can be, but is not limited to, a trench MOSFET (e.g., 900 in FIG. 9) fabricated by the manufacturing processes and steps shown in FIGS. 1-8. The switch 1010 can be used as a high-side power switch or a low-side power switch in the power conversion system 1000. Due to reduced poly sheet resistance of the trench MOSFET, the switch 1010 has relatively lower gate resistance. Advantageously, the switch 1010 can be turned on or off relatively faster and the efficiency of the power conversion system 1000 can be improved.

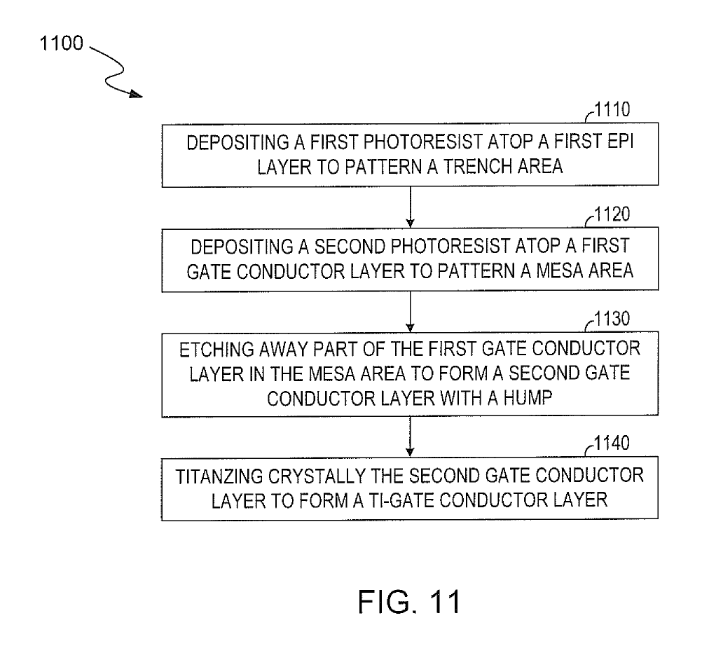

FIG. 11 illustrates a flowchart 1100 of a method of fabricating a cellular trench MOSFET, in accordance with one embodiment of the present invention. FIG. 11 is described in combination with FIG. 1-FIG. 8.

In block 1110, a first photoresist is deposited atop the first epitaxial (epi) layer to pattern a trench area. In block 1120, a second photoresist is deposited atop the gate conductor layer 205 to pattern a mesa area. The edges of the second photoresist are aligned to the edges of the first photoresist. In block 1130, part of the gate conductor layer 205 in the mesa area is etched away to form the gate conductor layer 405 with the hump 407. In block 1140, the gate conductor layer 405 is titanized crystally to form the Ti-gate conductor layer 605.

To summarize, a first photoresist is deposited atop an epi layer, e.g., a Nepi layer 110, to pattern a trench area. Part of the Nepi layer 110 in the trench area is etched to form a Nepi layer 201 and then the first photoresist is stripped. After a gate oxide layer 203 is grown around the Nepi layer 201, the trench is deposited by a gate conductor material and doped by POCl₃ to form a gate conductor layer 205 atop the gate oxide layer 203. A second photoresist is deposited atop the gate conductor layer 205 to pattern a mesa area. The edges of the second photoresist are aligned to the edges of the first photoresist. Afterwards, part of the gate conductor layer 205 in a mesa area is etched away to form a gate conductor layer 405 with a hump and then the second photoresist is stripped. Sequentially, after formation of P-wells, e.g., P-wells 510A and 510B acting as a trench body, N+ layers 520A and 520B are formed atop the P-wells 510A and 510B to act as a source region of a cellular trench MOSFET. P+ layers 720A and 720B are fabricated atop the P-wells 510A and 510B respectively as a body diode contact.

Ti film is deposited to form a Ti-gate conductor material in a Ti-gate conductor layer 605. The Ti in the mesa area can be etched away and the Ti-gate conductor material in the Ti-gate conductor layer 605 can be remained. Advantageously, the second photoresist is deposited to pattern the mesa area over the gate conductor layer 205 for the gate conductor structure. Therefore, more gate conductor material in the Ti-gate conductor layer 605 is converted to the Ti-gate conductor material. As a result, the sheet resistance of the cellular trench MOSFET can be reduced, e.g., from around 0.50 Ohm/SQ to around 0.130 Ohm/SQ, to enhance the gate conductivity of the cellular trench MOSFET. A spacer is formed to protect corners of the Ti-gate conductor layer 605 and to make the gate conductor structure more robust for mechanical support. Subsequently, a contact etching is performed and followed by a metallization step.

While the foregoing description and drawings represent embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

What is claimed is:

1. A method for fabricating a cellular trench metal oxide semiconductor field effect transistor (MOSFET), comprising:
depositing a first photoresist atop a first epitaxial (epi) layer to pattern a trench area;
depositing a second photoresist atop a first gate conductor layer to pattern a mesa area, wherein edges of said second photoresist are aligned to edges of said first photoresist;
etching away part of said first gate conductor layer in said mesa area to form a second gate conductor layer with a hump; and
titanizing crystally said second gate conductor layer to form a Ti-gate conductor layer.

2. The method of claim 1, further comprising:
etching away part of said first epi layer in said trench area to form a second epi layer; and
stripping said first photoresist after formation of said second epi layer.

3. The method of claim 2, further comprising:
growing an oxide layer around said second epi layer;
forming said first gate conductor layer atop said oxide layer before deposition of said second photoresist; and
stripping said second photoresist after formation of said second gate conductor layer.

4. The method of claim 2, further comprising:
forming a plurality of P-wells in an upper portion of said second epi layer after formation of said second gate conductor layer; and
forming a plurality of N-type heavily doped (N+) layers atop said P-wells respectively before titanization of said second gate conductor layer, wherein said N+ layers form a source region of said cellular trench MOSFET.

5. The method of claim 4, further comprising:
forming a plurality of spacers on sidewalls of said Ti-gate conductor layer;
forming a tetraethylorthosilicate and borophosphosilicate glass layer atop said Ti-gate conductor layer and around said spacers; and
forming a plurality of P+ layers adjacent to said N+ layers respectively.

6. The method of claim 1, wherein said hump is titanized crystally from the top and sidewalls of said hump simultaneously and wherein said second gate conductor layer below said hump is titanized crystally in a downward direction.

7. The method of claim 1, wherein approximately more than half of a gate conductor material in said second gate conductor layer is titanized crystally.

8. A cellular trench metal oxide semiconductor field effect transistor (MOSFET), comprising:
an epitaxial (epi) layer;
an oxide layer atop of said epi layer and inside a trench formed in said epi layer; and
a Ti-gate conductor layer filling said trench and forming a hump that extends outside said trench, wherein more than half of said Ti-gate conductor layer comprises Ti-gate conductor material.

9. The cellular trench MOSFET of claim 8, wherein a first photoresist is deposited to form said trench and then removed.

10. The cellular trench MOSFET of claim 8, wherein said hump is titanized crystally from the top and sidewalls of said hump simultaneously and wherein said Ti-gate conductor layer below said hump is titanized crystally in a downward direction.

11. The cellular trench MOSFET of claim 8, further comprising:
a plurality of P-wells atop said epi layer; and
a plurality of N+ layer atop said P-wells respectively and forming a source region of said cellular trench MOSFET.

12. The cellular trench MOSFET of claim 11, further comprising:
a plurality of spacers on sidewalls of said Ti-gate conductor layer;
a tetraethylorthosilicate and borophosphosilicate glass layer atop of said Ti-gate conductor layer and around said spacers; and
a plurality of P+ layers adjacent to said N+ layers respectively.

13. A power conversion system, comprising:
at least one switch, wherein said switch comprises a trench metal oxide semiconductor field effect transistor (MOSFET), wherein said trench MOSFET comprises a plurality of cellular trench MOSFETs, and wherein each of said cellular trench MOSFETs comprises:
an epitaxial (epi) layer;
an oxide layer atop of said epi layer and coating the bottom and sidewalls of a trench formed in said epi layer; and
a Ti-gate conductor layer with a hump that fills said trench, wherein more than half of said Ti-gate conductor layer comprises Ti-gate conductor material.

14. The power conversion system of claim 13, wherein a first photoresist is deposited to form said trench and then removed.

15. The power conversion system of claim 13, wherein said hump is titanized crystally from the top and sidewalls of said hump simultaneously and wherein said Ti-gate conductor layer below said hump is titanized crystally in a downward direction.

16. The power conversion system of claim 13, wherein each of said cellular trench MOSFETs further comprises:
a plurality of P-wells atop said epi layer; and
a plurality of N+ layer atop said P-wells respectively and forming a source region of said cellular trench MOSFET.

17. The power conversion system of claim 16, wherein each of said cellular trench MOSFETs further comprises:
a plurality of spacers on sidewalls of said Ti-gate conductor layer;
a tetraethylorthosilicate and borophosphosilicate glass layer atop of said Ti-gate conductor layer and around said spacers; and
a plurality of P+ layers adjacent to said N+ layers respectively.
